(19) United States
(12) Patent Application Publication
(10) Pub. No.: US 2013/0220952 A1
(43) Pub. Date: Aug. 29, 2013

(54) MOUNTING APPARATUS FOR HARD DISK DRIVE

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., ShenZhen City (CN)

(21) Appl. No.: 13/433,310

(22) Filed: Mar. 29, 2012

(30) Foreign Application Priority Data
Feb. 27, 2012 (CN) 201210045257.X

(51) Int. Cl. H05K 7/14

(52) U.S. Cl. 211/26

(57) ABSTRACT

A mounting apparatus for a hard disk drive includes a chassis, a supporting bracket, a latching member slidably installed to the supporting bracket, and an elastic member sandwiched between the supporting bracket and the latching member. The chassis includes a bottom wall. A protrusion protrudes up from the bottom wall. The supporting bracket includes an installation plate, two side plates extending down from two opposite sides of the installation plate, and two supporting plates extending from bottom sides of the corresponding side plates. The supporting plates are mounted on the bottom wall. The elastic member abuts against the latching member to engage with the protrusion. A number of first tabs extend from each side plate toward the other side plate, for supporting the hard disk drive. A first space is defined between the first tabs and the supporting plates.

### BACKGROUND

1. Technical Field

The present disclosure relates to mounting apparatus, and particularly to a mounting apparatus for a hard disk drive.

2. Description of Related Art

In a server, many hard disk drives are tightly arranged in a chassis of the server. However, the hard disk drives generate a large amount of heat during operation, and the heat dissipation is not efficient.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the views.

FIG. 1 is an partially exploded, isometric view of an exemplary embodiment of a mounting apparatus together with a plurality of hard disk drives, wherein the mounting apparatus includes a plurality of supporting brackets, and a plurality of latching members.

FIG. 2 is an exploded, isometric view of one of the supporting brackets, one of the latching members, and one of the hard disk drives of FIG. 1.

FIG. 3 is an inverted view of FIG. 2.

FIG. 4 is an assembled, isometric view of FIG. 1.

FIG. 5 is a cross-sectional view of FIG. 4, taken along the line of V-V.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references can mean “at least one.”

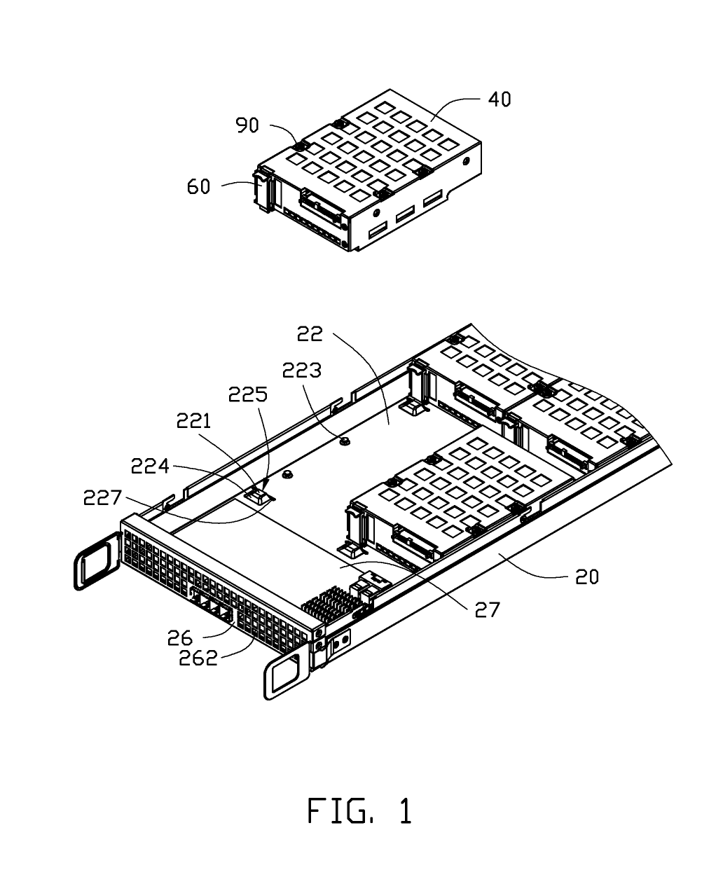

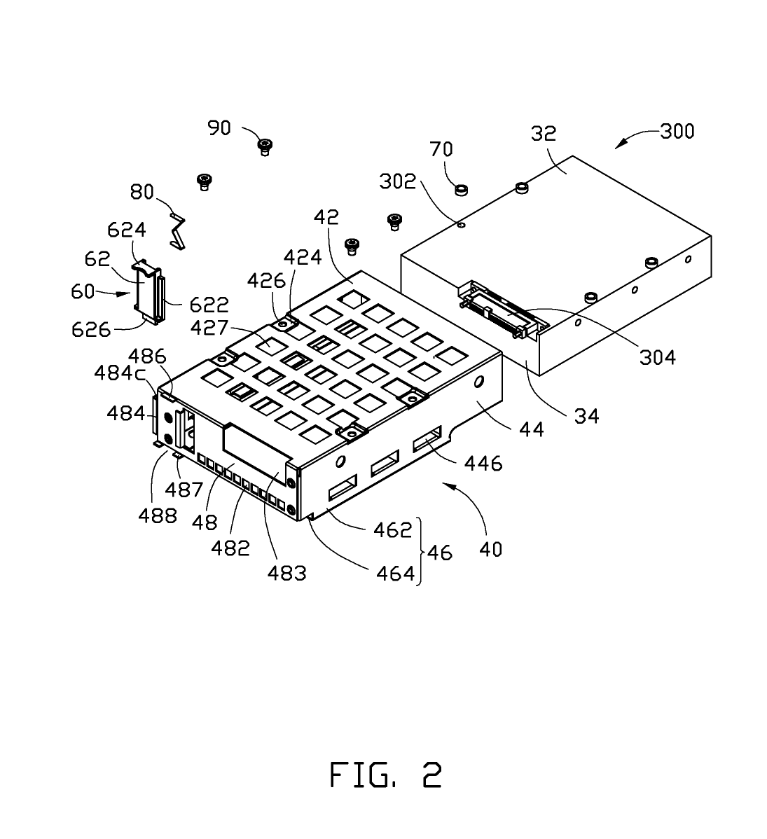

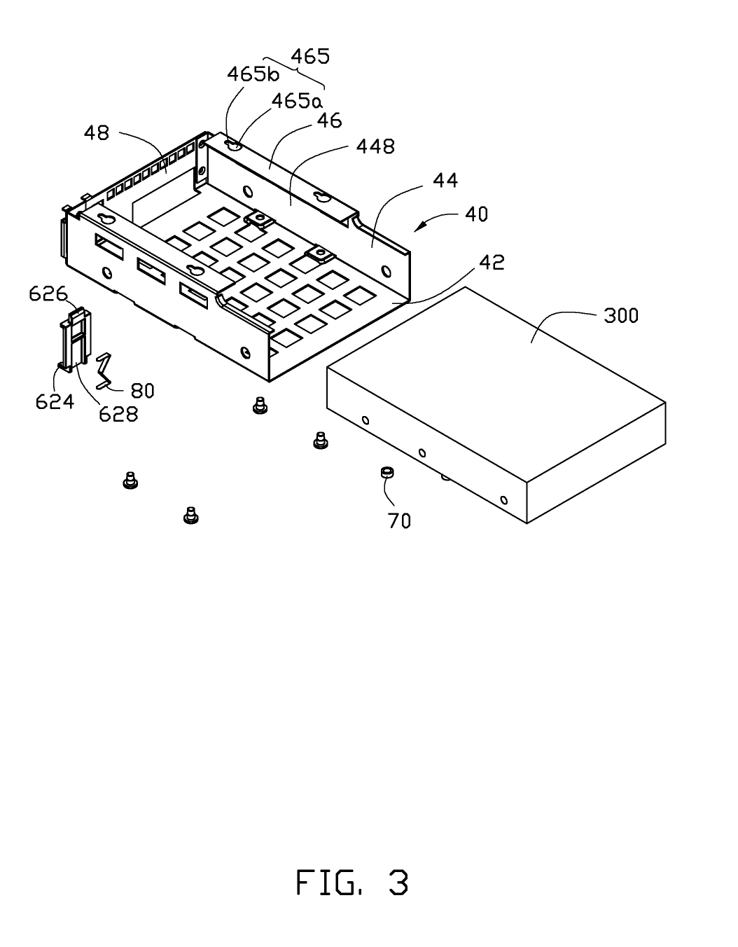

FIGS. 1-3, show an exemplary embodiment of a mounting apparatus provided for mounting a plurality of hard disk drives 300. Each hard disk drive 300 includes a connecting surface 32 defining a plurality of screw holes 302, and an end surface 34 perpendicularly extending down from an end of the connecting surface 32. A connector 304 is mounted on an end of the end surface 34. The mounting apparatus includes a chassis 20, a plurality of supporting brackets 40, a plurality of latching members 60, a plurality of shockproof members 70, a plurality of elastic members 80, and a plurality of screws 90.

The chassis 20 includes a rectangular bottom wall 22 and an end wall 26 perpendicularly extending up from an end of the bottom wall 22. A plurality of protrusions 221 protrudes up from the bottom wall 22. Four substantially mushroom-shaped positioning posts 223 extend up from the bottom wall 22, at a side of each protrusion 221 away from the end wall 26. A first side of each protrusion 221 adjacent to the end wall 26 forms a slantwise guiding surface 224. A second side of each protrusion 221 opposite to the first side forms a stopping surface 225 substantially perpendicular to the bottom wall 22. A slot 227 is defined in the bottom wall 22 adjacent to each stopping surface 225. A circuit board 27 is mounted on the bottom wall 22, adjacent to the end wall 26. The end wall 26 defines a plurality of vents 262.

Each supporting bracket 40 includes a rectangular installation plate 42, two side plates 44 perpendicularly extending down from two opposite sides of the installation plate 42, an end plate 48 perpendicularly extending down from an end of the installation plate 42, and two substantially L-shaped supporting plates 46 extending from bottom sides of the side plates 44 and adjacent to the end plate 48. A plurality of tabs 446 perpendicularly extends from the bottom side of each side plate 44 toward the other side plate 44, above the supporting plates 46. The tabs 446 and the installation plate 42 cooperatively bound a receiving space 448.

A plurality of depression portions 424 is defined in a top of the installation plate 42. A bottom wall of each depression portion 424 defines a through hole 426. The installation plate 42 defines a plurality of vents 427.

Each supporting plate 46 includes an extending portion 462 extending down from the corresponding side plate 44, and a rectangular supporting portion 464 perpendicularly extending in toward the other supporting plate 46 from a bottom side of the extending portion 462 and below the corresponding tabs 446. Each supporting portion 464 defines two spaced holding holes 465 aligned with each other along the lengthwise direction of the installation plate 42. Each holding hole 465 includes an access 465a away from the end plate 48, and a holding portion 465b communicating with the access 465a and adjacent to the end plate 48. The access 465a has a size larger than the holding portion 465b.

A first end of the end plate 48 defines an opening 483 through which the connector 304 of the hard disk drive 300 extends. Two substantially L-shaped guiding pieces 484 extend out from a second end of the end plate 48 opposite to the first end. Each guiding piece 484 and the end plate 48 cooperatively bound a slide slot 484c extending along a direction perpendicular to the installation plate 42. A tab 486 extends out from a top of the end plate 48 between the guiding pieces 484. Two stopping pieces 487 extend out from a bottom of the end plate 48 between the guiding pieces 484. A cutout 488 is defined between the stopping pieces 487. The end plate 48 defines a plurality of vents 482.

Each latching member 60 includes a rectangular main body 62, two rails 622 extending out from two opposite sides of the main body 62, an operation portion 624 perpendicularly extending out from a first end of the main body 62, and a latching block 626 extending down from a second end of the main body 62 opposite to the first end. The main body 62 defines a receiving slot 628 opposite to the operation portion 624.

In the embodiment, each shockproof member 70 is annular, and is made of shockproof material, such as plastic or rubber.

In the embodiment, the elastic member 80 is a substantially M-shaped elastic piece.

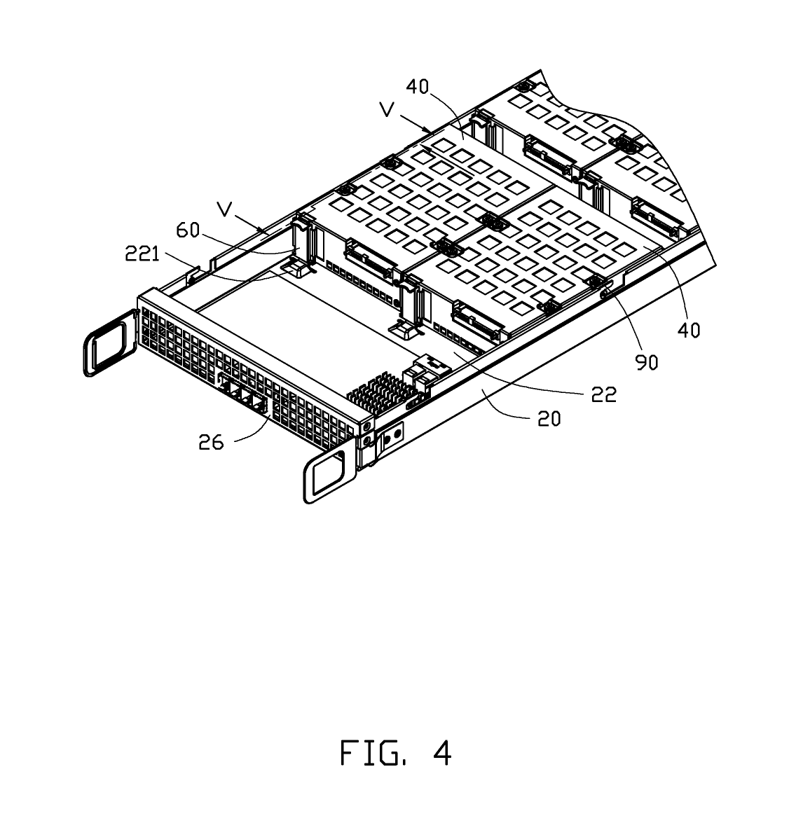

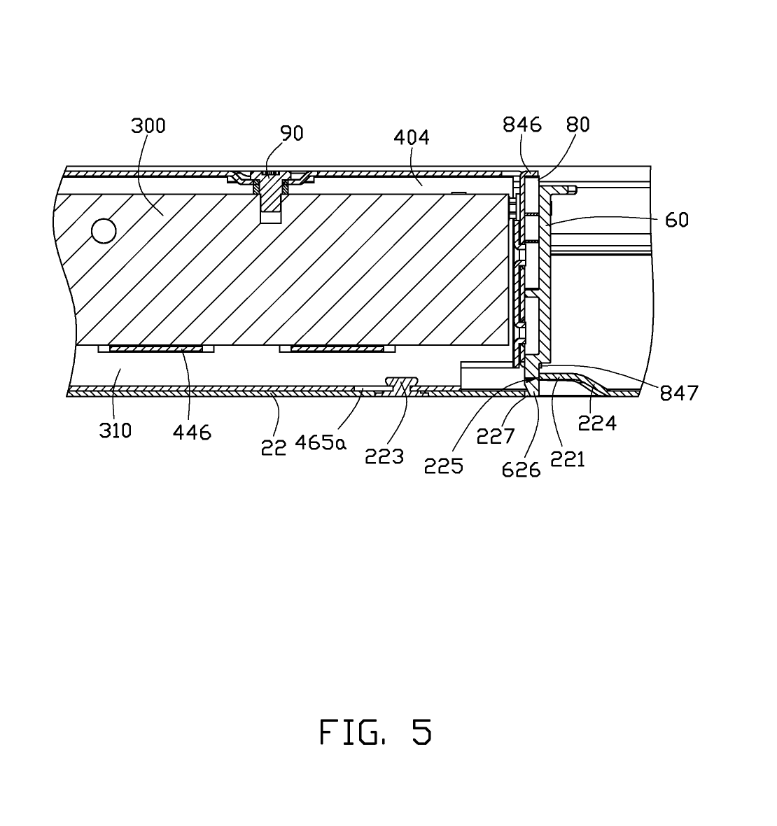

FIGS. 4 and 5, show in assembly, the elastic member 80 is received in the receiving slot 628 of the latching member 60. A first end of the elastic member 80 is received within the receiving slot 628 and abuts against the main body 62, and a second end of the elastic member 80 opposite to the first end is exposed out of the receiving slot 628. The rails 622 of the latching member 60 are slidably received in the corresponding slide slots 484c. The second end of the elastic member 80 resiliently abuts against the tab 486. The second end of the main body 62 is supported on the stopping pieces 487, and the latching block 626 extends through the cutout 488. The latching member 60 can slide along a direction perpendicular to the installation plate 42.

The shockproof members 70 are adhered to the connecting surface 32 of the hard disk drive 300, aligning with the corresponding screw holes 302. The combination of the shockproof members 70 and the hard disk drive 300 is inserted into the receiving space 448. The hard disk drive 300 is supported on the tabs 446. The connector 304 extends through the opening 483. The screw holes 302 align with the corresponding through holes 426 of the installation plate 42. The screws 90 extend through the through holes 426, the shockproof members 70, and are screwed into the corresponding screw holes 302. The shockproof members 70 are sandwiched between the installation plate 42 and the hard disk drive 300, to absorb vibrations, thereby protecting the hard disk drive 300. A first space 404 is defined between the installation plate 42 and the connecting surface 32, for ventilation.

The combination of the supporting bracket 40, the hard disk drive 300, and the latching member 60 is installed to the chassis 20. The access 465a of each holding hole 465 aligns with the corresponding positioning post 223 of the chassis 20. Each positioning post 223 is inserted into the corresponding access 465a. The supporting bracket 40 is pushed away from the end wall 26 to make the positioning posts 223 move toward the corresponding holding portions 465b of the holding holes 465. The latching block 626 slidably abuts against the guiding surface 224 of the corresponding protrusion 221 to cause the rails 622 to slide up along the corresponding slide slots 484c, deforming the elastic member 80. The positioning posts 223 enter the corresponding holding portions 465b, and the latching block 626 passes through the protrusion 221 to align with the slot 227. The elastic member 80 is self-restored to bias the latching member 60 to abut against the stopping surface 225. A bottom end of the latching block 626 is latched into the slot 227. A second space 310 is defined between the hard disk drive 300 and the bottom wall 22 of the chassis 20, for ventilation, and electrical wires of another hard disk drive 300 can extend through the second space 310.

In disassembling the hard disk drive 300, the operation portion 624 is manipulated away from the bottom wall 22. The latching member 60 slides up, deforming the elastic member 80. The latching block 626 is disengaged from the slot 227. After the latching block 626 moves up to disengage from the stopping surface 225, the supporting bracket 40 is moved toward the end wall 26. After the latching block 626 passes through the protrusion 221, the positioning posts 223 enter the corresponding accesses 465a. Therefore, the supporting bracket 40 can be easily removed from the bottom wall 22 of the chassis 20.

While the disclosure describes examples and embodiments, it is to be understood that the disclosure is not limited thereto. To the contrary, the disclosure is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A mounting apparatus for a hard disk drive, comprising:
a chassis comprising a bottom wall;
a supporting bracket comprising an installation plate, two side plates extending down from two opposite sides of the installation plate, and two supporting plates extending from bottom sides of the corresponding side plates;
a latching member slidably installed to the supporting bracket from top to bottom ; and
an elastic member sandwiched between the supporting bracket and the latching member, and abutting against the latching member to latch with the bottom wall, wherein the supporting plates are mounted on the bottom wall, a plurality of first tabs extends from the bottom side of each side plate above the supporting plates toward the other side plate, for supporting the hard disk drive, a first space is defined between the first tabs and the supporting plates.

2. The mounting apparatus of claim 1, wherein a plurality of depression portions is defined in a top of the installation plate, a bottom wall of each depression portion defines a through hole, a plurality of screws extend through the through holes, a plurality of shockproof members, to be mounted to the hard disk drive, a second space is defined between the installation plate and the hard disk drive.

3. The mounting apparatus of claim 1, wherein each supporting plate comprises an extending portion down extending from the corresponding side plate, and a supporting portion perpendicularly extending toward the other supporting plate from a bottom side of the extending portion and below the corresponding first tabs, each supporting portion is detachably mounted on the bottom wall.

4. The mounting apparatus of claim 3, wherein a plurality of mushroom-shaped positioning posts extend up from the bottom wall, each supporting portion defines a plurality of holding holes, each positioning post is detachably inserted into a corresponding holding hole.

5. The mounting apparatus of claim 4, wherein each holding hole comprises an access and a holding portion communicating with the access, the access is larger than the holding portion in size, each positioning post is inserted into the corresponding holding portion through the corresponding access portion.

6. The mounting apparatus of claim 1, wherein the supporting bracket further comprises an end plate perpendicularly extending down from an end of the installation plate, two opposite guiding pieces extend out from the end plate, each guiding piece and the end plate cooperatively bound a slide slot, the latching member comprises a main body and two rails extending out from two opposite sides of the main body to be slidably received in the corresponding slide slots.

7. The mounting apparatus of claim 6, wherein a protrusion protrudes up from the bottom wall, a latching block extends down from a first end of the main body, two stopping pieces extend out from a bottom of the end plate between the guiding pieces for supporting the main body, a cutout is defined between the stopping pieces, the latching block extends through the cutout to engage with the protrusion.

8. The mounting apparatus of claim 7, wherein an operation portion perpendicularly extending out from a second end of the main body opposite to the latching block, the operation portion is manipulated to slide the latching member.

9. The mounting apparatus of claim 7, wherein the protrusion comprises a stopping surface, substantially perpendicular to the bottom wall, the latching block is engaged with the stop surface.

10. The mounting apparatus of claim 9, wherein the protrusion further comprises a slantwise guiding surface opposite to the stop surface, the latching block slidably abuts against the guiding surface, for passing through the protrusion.

11. The mounting apparatus of claim 9, wherein the bottom wall defines a slot adjacent to the stopping surface, the latching block is inserted into the slot.

12. The mounting apparatus of claim 6, wherein the main body defines a receiving space, the elastic member is received in the receiving slot, a second tab extends out from a top of the end plate, a first end of the elastic member is received within the receiving slot and abuts against the main body, and a second end of the elastic member opposite to the first end resiliently abuts against the second tab.
